(19) United States
(12) Patent Application Publication
(10) Pub. No.: US 2002/0070425 A1
(43) Pub. Date: Jun. 13, 2002

(54) RF power bipolar junction transistor having performance-enhancing emitter structure

(75) Inventors: Howard Dwight Bartlow, West Linn, OR (US); Chris John Knorr, Los Gatos, CA (US)

Correspondence Address: Henry K. Woodward, TOWNSEND and TOWNSEND and CREW LLP, Two Embarcadero Center, 8th Floor, San Francisco, CA, 94111-3834, US

(73) Assignee: SPECTRIAN CORPORATION

(21) Appl. No.: 09/736,888

(22) Filed: Dec. 13, 2000

(51) Int. Cl. H01L 27/082; H01L 29/70

(52) U.S. Cl. 257/578; 257/579

(57) ABSTRACT

Performance of an RF power bipolar transistor having a collector region, at least one base region, and a plurality of elongated emitter fingers in each major region, is enhanced by forming each emitter finger with at least two spaced segments and contacting the two spaced segments with a metal lead. By eliminating the middle portion of each emitter finger, current hogging at the central portion and hot spot generation are eliminated. Power output is maintained with reduced emitter lengths by minimizing the adverse affects of the hot spot generation in the emitters.

### BACKGROUND OF THE INVENTION

This invention relates generally to bipolar transistors, and more particularly, the invention relates to a bipolar transistor having an emitter structure for enhanced RF and microwave power applications.

RF power bipolar transistors typically comprise a substrate which functions as a collector with one or more base regions formed by dopants in one surface of the substrate. The emitter comprises a plurality of elongated doped regions or fingers in each base region with an inter-digitated metal contact structure connecting all emitter doped regions in parallel and with other inter-digitated metal contacts connected to the base. The multiple emitter fingers enhance the current and power capacity of the transistor.

The RF power bipolar structure has a recognized problem with uneven current distribution in each emitter finger which leads to a hot spot developing in the middle portion of the finger. See for example, Liu, “The Temperature and Current Profiles in an Emitter Finger as a Function of the Finger Length”, Solid State Electronics, volume 36, No. 12, Pages 1787-1789, 1993. As discussed by Liu, microwave power bipolar transistors have multi-emitter fingers to increase the total device power output, as noted above. If the emitter finger length is short, there needs to be more fingers for a given desired total emitter length (current and power capacity), and this increases chip size and causes the circuit to suffer distributive effects as the size approaches the wave length corresponding to the operating frequency. However, if the emitter length is made too long, the current distribution ceases being uniform and a significant portion of an emitter finger does not contribute to the transistor action. This non-uniform current distribution leads to an increase in temperature at the center of the emitter finger and decreases toward either end of the finger. Liu proposes to address the problem by increasing the contact resistance of the inter-digitated metal contacts to the emitter fingers. However, the increase in the emitter contact resistance is difficult to maintain, and the increase in resistance also leads to a loss of power.

The present invention is directed to enhancing device ruggedness and performance without adversely affecting output power of an RF bipolar transistor.

### SUMMARY OF THE INVENTION

In accordance with the invention, the performance of an RF power bipolar transistor is enhanced without adversely affecting power output by providing a plurality of elongated emitter fingers in each base region of the transistor with each emitter finger having at least two spaced segments. The at least two spaced segments are then contacted by a metal lead which can be part of an inter-digitated metal contact structure. By enhancing the current capacity of each segment, the current capacity of the emitter is not adversely affected as compared with an emitter finger having one elongated segment. By eliminating a hot spot in the middle portion of the emitter finger, device ruggedness and performance is improved without loss of power.

In a preferred embodiment, the RF bipolar transistor is formed in a semiconductor body of a first conductivity type having first and second opposing major surfaces. The semiconductor body can comprise a silicon substrate with an epitaxial silicon layer thereon. At least one base region is formed in one major surface of the semiconductor body by dopants of a second conductivity type. A plurality of elongated emitter fingers of the first conductivity type are then formed in the base region, the emitter fingers being in a spaced parallel configuration with at least some emitter region having a plurality of segments which are spaced apart in a middle portion of the finger. An electrical contact is made to all segments of each finger with the emitter contacts preferably forming an inter-digitated contact structure with base contacts. In an emitter finger configuration having four or more spaced segments, the middle segments may be spaced farther apart than are other segments of the finger.

The invention and objects and features thereof will be more readily apparent when the following detailed description and appended claims are taken with the drawing.

### BRIEF DESCRIPTION OF THE DRAWINGS

FIG. 1 is a perspective view of an RF power transistor in accordance with prior art.

FIG. 2 is a plan view of a portion of the transistor of FIG. 1 showing the base region and a plurality of elongated emitter fingers in accordance with the prior art.

FIG. 3 is a plan view of a base region of an RF power transistor having a plurality of elongated emitter fingers in accordance with one embodiment of the invention.

FIG. 4 is a plan view of a base region and an RF power bipolar transistor having a plurality of elongated emitter regions in accordance with another embodiment of the invention.

### DETAILED DESCRIPTION OF ILLUSTRATED EMBODIMENTS

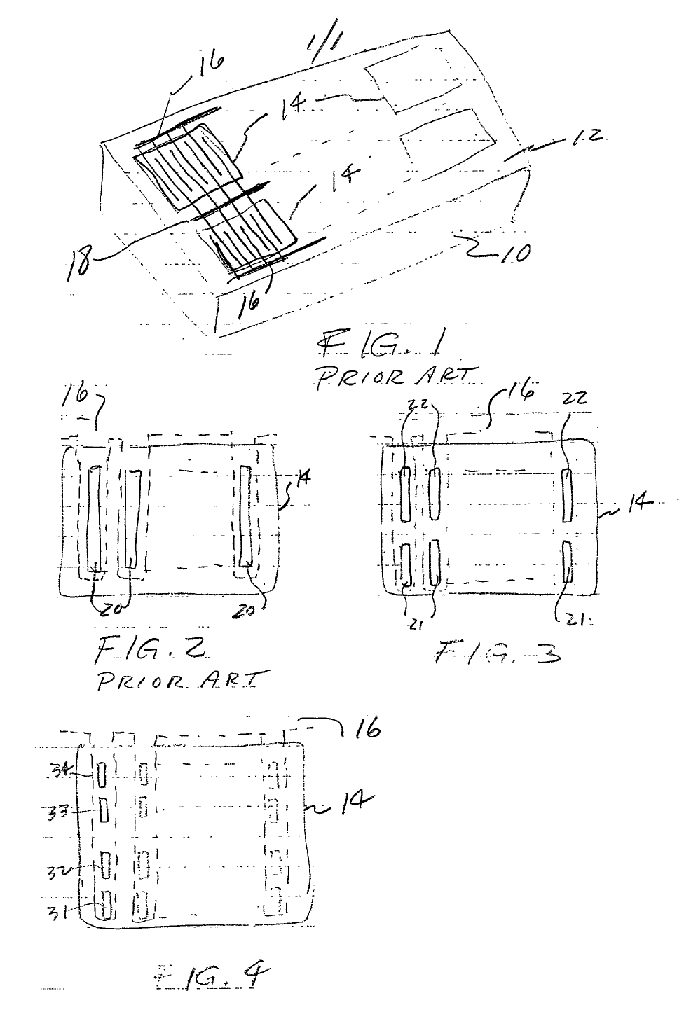

FIG. 1 is a perspective view of an RF power bipolar transistor in accordance with the prior art which includes a silicon semiconductor body 10 of one conductivity type which has a major face 12 in which a plurality of base regions 14 are formed by dopant of opposite conductivity type. A plurality of emitter fingers are formed in each base region which are contacted by first inter-digitated metal contacts 16. A second set of inter-digitated contacts 18 contact the base region between adjacent emitter fingers in the base region.

In one embodiment the semiconductor body 10 comprises a silicon substrate having N+ plus conductivity of 10¹⁸-10¹⁹ atoms/cc with an N-doped epitaxial layer formed on the surface of the substrate and having a resistance of 1.5-3.0 ohms-centimeter. Base regions 14 are P doped with a resistance on the order of 300 ohms/square, and the elongated emitter fingers in each base region are N+ conductivity with a dopant concentration on the order of 10¹⁹-10²⁰ atoms/cc.

FIG. 2 is a plan view of one base region 14 of FIG. 1 with the elongated emitter fingers 20 formed therein, the metal contacts 16 are shown by a dotted line and extend over and engage each of the elongated emitter fingers 20. The base metallization 18 is not shown in this view but would lie between the metal contacts 16 to the emitter fingers 20 in an inter-digitated fashion as illustrated in FIG. 1.

As noted above, the RF power bipolar structure has a recognized problem with uneven current distribution in each emitter finger which leads to a hot spot developing in the middle portion of the finger due to current hogging until saturation limits performance. This leads to ruggedness, efficiency, temperature failure mechanisms which affect performance of the transistor and may cause eventual failure of the device. The problem becomes more acute as the emitter fingers increase in length.

In accordance with the invention, device performance and ruggedness is improved without adversely affecting power output of the transistor by eliminating a central portion of each emitter finger as illustrated in the embodiment of FIG. 3. In this embodiment each emitter finger 20 of FIG. 2 has two segments (21, 22) with these two segments spaced apart in a middle portion of the emitter finger. Each metal contact 16 to an emitter finger contacts both segments so that the emitter segments are interconnected, but emitter current does not flow through the central portion of each elongated emitter. The section of each emitter finger which is eliminated is calculated or determined empirically based on transistor operating frequency, power output, and transistor configuration. By eliminating the heat generated in the central portion of each emitter, the performance and ruggedness of a transistor is improved without sacrifice of transistor power. Using two segments for each emitter finger, the removal of approximately 20% of the central portion of the emitter finger has proved to be in a workable range.

FIG. 4 is another embodiment of the invention in which each emitter finger is divided into four segments (31-34). Each emitter segment is spaced from the adjacent emitter segment with the middle two segments (32, 33) possibly being spaced farther apart than are an end segment and a middle segment such as segments 31, 32 and segments 33, 34.

The use of segmented emitter fingers in an RF power transistor has proved to be particularly useful in high frequency and microwave applications. While the invention has been described with reference to specific embodiments, the description is illustrative of the invention and is not be construed as limiting the invention. For example, the invention can be used with III-V semiconductor material transistors and with heterojunction transistors. Thus, various modifications and applications may occur to those skilled in the art without departing from the true spirit and scope of the invention as defined by the appended claims.

What is claimed is:

1. An RF power bipolar transistor having emitter, base, and collector regions comprising:
a) a semiconductor body of first conductivity type and having first and second opposing major surfaces,
b) at least one base region formed in the first major surface by dopants of a second conductivity type, and
c) a plurality of elongated emitter fingers of the first conductivity type formed in the base region, the emitter fingers being in a spaced parallel configuration with each emitter finger having at least two segments which are spaced apart in a middle portion of the finger.

2. The RF power bipolar transistor as defined by claim 1 and further including a first plurality of metal contacts to emitter fingers and a second plurality of metal contacts to the base region, the first and second plurality of contacts being inter-digitated.

3. The RF power bipolar transistor as defined by claim 2 wherein each emitter finger has four segments linearly arranged and spaced apart from each other.

4. The RF power bipolar transistor as defined by claim 3 wherein the middle two segments are spaced farther apart than are an end segment and a middle segment.

5. The RF power bipolar transistor as defined by claim 4 wherein the semiconductor body is N conductivity type, the base region is P conductivity type and the emitter fingers are N conductivity type.

6. The RF power bipolar transistor as defined by claim 5 and including a plurality of base regions.

7. The RF power bipolar transistor as defined by claim 6 wherein the semiconductor body comprises a silicon substrate and an epitaxial semiconductor layer, the base regions and the emitter fingers are formed in the epitaxial semiconductor layer.

8. The RF power bipolar transistor as defined by claim 2 wherein each emitter finger has a plurality of segments linearly arranged and spaced apart from each other.

9. The RF power bipolar transistor as defined by claim 8 wherein the middle two segments are spaced farther apart than are other segments.

10. The RF power bipolar transistor as defined by claim 9 wherein the semiconductor body is N conductivity type, the base region is P conductivity type, and the emitter fingers are N conductivity type.

11. The RF power bipolar transistor as defined by claim 10 and including a plurality of base regions.

12. The RF power bipolar transistor as defined by claim 11 wherein the semiconductor body comprises a silicon substrate and an epitaxial semiconductor layer, the base regions and the emitter fingers are formed in the epitaxial semiconductor layer.

13. The RF power bipolar transistor as defined by claim 1 and including a plurality of base regions.

14. The RF power bipolar transistor as defined by claim 13 wherein the semiconductor body is N conductivity type, the base region is P conductivity type, and the emitter fingers are N conductivity type.

15. The RF power bipolar transistor as defined by claim 14 wherein the semiconductor body comprises a silicon substrate and an epitaxial semiconductor layer, the base regions and the emitter fingers are formed in the epitaxial semiconductor layer.

16. In a RF power bipolar transistor having a collector region, at least one base region, and a plurality of elongated emitter fingers in each base region, a method of enhancing transistor performance comprising the steps of:
a) forming each emitter finger with at least two spaced segments, and
b) contacting the at least two spaced segments with a metal lead.

17. The method as defined by claim 16 wherein step a) forms each emitter finger with at least four spaced segments.

18. The method as defined by claim 17 wherein the middle two segments are spaced farther apart than are the other segments of an emitter finger.
